(19) United States
(12) Patent Application Publication
(10) Pub. No.: US 2014/0356052 A1
(43) Pub. Date: Dec. 4, 2014

(54) HOT MELT ASSEMBLY STRUCTURE AND ASSEMBLY METHOD THEREOF

(71) Applicants: INVENTEC CORPORATION, Taipei (TW); Inventec (Pudong) Technology Corporation, Shanghai (CN)

(72) Inventors: Chien-Hung CHEN, Taipei (TW); Ping-Huang KUO, Taipei (TW)

(73) Assignees: INVENTEC CORPORATION, Taipei (TW); Inventec (Pudong) Technology Corporation, Shanghai (CN)

(21) Appl. No.: 14/243,688

(22) Filed: Apr. 2, 2014

(30) Foreign Application Priority Data
May 30, 2013 (CN) 201310207871.6

(51) Int. Cl. H05K 5/02

(52) U.S. Cl. CPC H05K 5/0217
USPC 403/267

(57) ABSTRACT

A hot melt assembly structure includes a support member and an assembly member. The support member has a hot melt hole and at least one rib adjacent to the hot melt hole. The assembly member includes a main body and a hot melt body connected to the main body. The hot melt body includes a neck part and a cap part. The neck part connects the main body with the cap part. The neck part is disposed through the hot melt hole and the cap part leans against the rib.

### CROSS-REFERENCE TO RELATED APPLICATIONS

This non-provisional application claims priority under 35 U.S.C. §119(a) on Patent Application No(s). 201310207871.6 filed in China, P.R.C. on May 30, 2013, the entire contents of which are hereby incorporated by reference.

### BACKGROUND

1. Technical Field of the Invention

The disclosure relates to an assembly structure, more particularly to a hot melt assembly structure.

2. Description of the Related Art

Due to the features of being slim and light, the laptop has become the mainstream of the current market and has gradually replaced the desktop. In order to manufacture a slim and light laptop, most of laptop's components are required to be slim in size.

To fully take laptop's advantages of being slim and light, the assembly of the laptop has gradually shifted from assembly by screw lock to hot melt assembly. Additionally, to improve the performance of the laptop, the manufacturers often reduce the space for hot melt structure in order to increase the space for other electronic components. The decrease of the space for hot melt structure, however, may be detrimental to the reliability of the assembly of the electronic device. Therefore, how to strike a balance between the performance of the electronic device and the reliability of the assembly is a crucial issue to be addressed for the manufacturers.

### SUMMARY OF THE INVENTION

A hot melt assembly structure comprises a support member and an assembly member. The support member has a hot melt hole and at least one rib adjacent to the hot melt hole. The assembly member comprises a main body and a hot melt body connected to the main body. The hot melt body comprises a neck part and a cap part. The neck part connects the main body with the cap part. The neck part is disposed through the hot melt hole and the cap part leans against the rib.

### BRIEF DESCRIPTION OF THE DRAWINGS

The disclosure will become more fully understood from the detailed description given herein below for illustration only and thus does not limit of the disclosure, wherein:

FIG. 1 is a perspective view of a hot melt assembly structure according to the first embodiment of the disclosure;

FIG. 2 is an exploded view of FIG. 1; and

FIG. 3 and FIG. 4 are schematic views of the assembly of FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known components and devices are schematically shown in order to simplify the drawing.

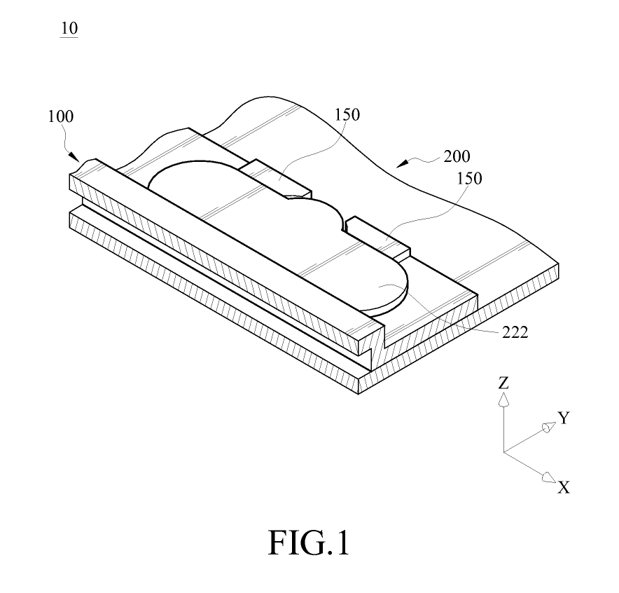

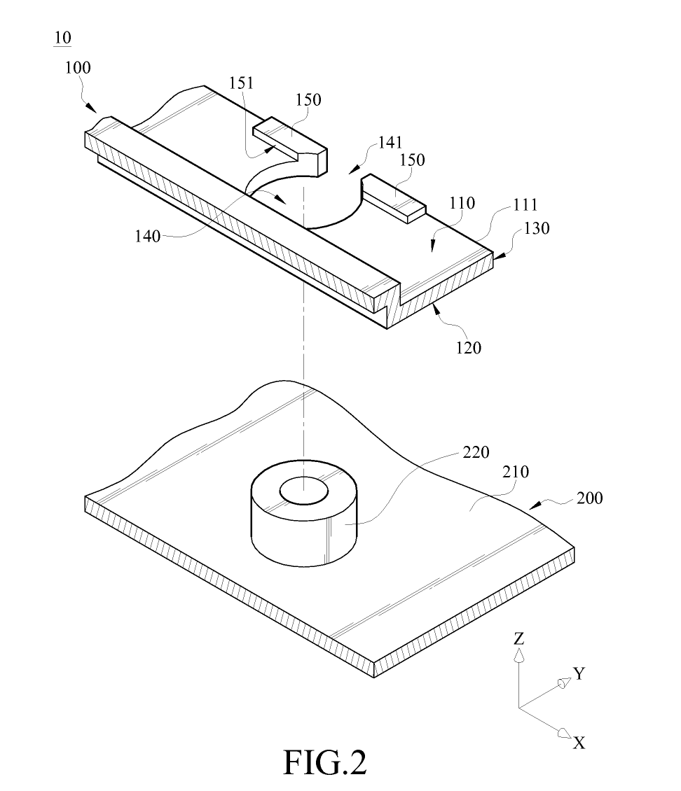

Referring to FIG. 1 and FIG. 2, FIG. 1 is a perspective view of a hot melt assembly structure according to the first embodiment of the disclosure; FIG. 2 is an exploded view of FIG. 1.

The hot melt assembly structure 10 of this embodiment comprises a support member 100 and an assembly member 200. The support member 100 has a first surface 110, a second surface 120 and a third surface 130. The first surface 110 and the second surface 120 are located on the two opposite sides of the support member 100 respectively. The third surface is connected between the first surface 110 and the second surface 120. Moreover, the first surface 110 has a lateral side 111 connected to the third surface 130. Additionally, the support member 100 has a heat melt hole 140 penetrating the first surface 110 to the second surface 120. The heat melt hole 140 has an opening 141 located on the third surface 130. The support member 100 has two ribs 150 disposed on the first surface 110 and near the opening 141. Specifically, in this embodiment, the two ribs are located on the lateral side 111 of the first surface 110, and the opening 141 is located between the two ribs. Furthermore, the rib 150 has a lateral side 151 connected with the first surface 110.

In this embodiment, the number of the rib 150 is two, but the disclosure is not limited thereto. In other embodiments, the number of the rib 150 may be one or more than three. Moreover, in this embodiment, the rib 150 is located on the lateral side 111 of the first surface 110, but it is not intended to limit the disclosure. In other embodiments, the rib 150 may be at any location on the first surface as long as it is separated by a distance from the opposite side of the lateral side 111.

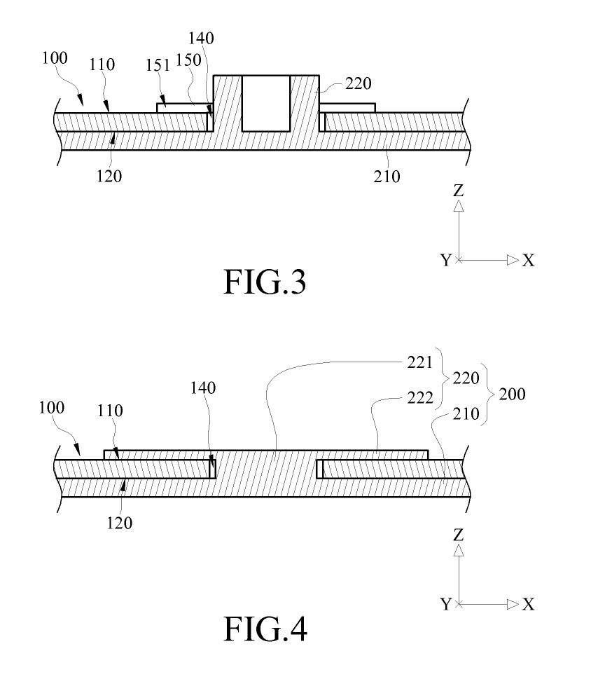

The assembly member 200 comprises a main body 210 and a hot melt body 220. The hot melt body 220 is a thermoplastic. The melting point of the material of the support member 100 is greater than the melting point of the material of the heat melt body 220. Furthermore, the assembly method of the heat melt assembly structure 10 is set forth in the following description. Referring to FIG. 3 and FIG. 4, FIG. 3 and FIG. 4 are schematic views of the assembly of FIG. 1.

Firstly, as seen in FIG. 3, the hot melt body 220 of the assembly member 200 is disposed through the hot melt hole 140 of the support member 100. Specifically, the hot melt body 220 runs through one side near the second surface 120 of the hot melt hole 140 and protrudes from the first side 110 of the support member 100.

Subsequently, as seen in FIG. 4, melting the part of the hot melt body 220 protruding from the first surface 110 makes the part of the hot melt body 220 inside the hot melt hole 140 be defined as a neck part 221, while make the part of the hot melt body 220 deformed by the melting process be defined as a cap part 222. The neck part 221 is connected to the main body 210. The cap part 222 is connected to the neck part 221. In one embodiment, the neck part 221 and the cap part 222 are integrally formed. The support member 100 is disposed between the cap part 222 and the main body 210, so that the movement between the support member 100 and the assembly member 200 along the positive z axis is limited. Furthermore, the cap part 222 leans against the first surface 110 and the lateral side 151 of the rib 150. In a limited space for hot melt assembly, since the rib 150 is located on the lateral side 111, near the opening 141, of the first surface 110, the rib 150 can abut against the cap part 222 of the assembly member 200, so as to limit the movement of the assembly member 200 along the positive z axis. Thereby, the rib 150 is not only configured for preventing the heat melt body 220 of the assembly member 200 from detaching from the support member 100 in a direction towards the opening 141, but also configured for reinforcing the capability of resistance to bending deformation of the assembly member 200. Thereby, the reliability of the assembly of the hot melt assembly structure 10 is improved.

According to the hot melt assembly structure and assembly method thereof of the disclosure, in a limited space for hot melt assembly, through the rib abutting against the cap part of the assembly member, the assembly member's capability of resistance to bending deformation is reinforced, and this also prevents the heat melt body of the assembly member from detaching from the support member in a direction towards the opening. Thereby, the reliability of the assembly of the hot melt assembly structure is enhanced.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A hot melt assembly structure comprising:
a support member having a hot melt hole and at least one rib adjacent to the hot melt hole; and
an assembly member comprising a main body and a hot melt body connected to the main body, the hot melt body comprising a neck part and a cap part, the neck part connecting the main body with the cap part, the neck part being disposed through the hot melt hole, the cap part leaning against the rib.

2. The hot melt assembly structure according to claim 1, wherein the support member has a first surface, a second surface and a third surface, the first surface and the second surface being located at two opposite sides of the support member respectively, the third surface being connected to the first surface and the second surface, the main body leaning against the second surface, the cap part leaning against the first surface.

3. The hot melt assembly structure according to claim 2, wherein the hot melt hole penetrates through the first surface and the second surface.

4. The hot melt assembly structure according to claim 2, wherein the hot melt hole has an opening located on the third surface and adjacent to the at least one rib.

5. The hot melt assembly structure according to claim 1, wherein the neck part and the cap part are integrally formed.

6. The hot melt assembly structure according to claim 2, wherein the first surface has a lateral side connected to the third surface, and the at least one rib is located on the lateral side of the first surface.

7. The hot melt assembly structure according to claim 2, wherein the first surface has a lateral side near the third surface, the number of the at least one rib is two, the two ribs are located on the lateral side of the first surface and the opening is located between the two ribs.

8. The hot melt assembly structure according to claim 2, wherein the rib has a lateral side connecting the first surface, and the cap part leans against the first surface and the lateral side.

9. The hot melt assembly structure according to claim 1, wherein the hot melt body is a thermoplastic.

10. The hot melt assembly structure according to claim 1, wherein the melting point of the material of the support member is greater than the melting point of the material of the hot melt body.
